(19) United States
(12) Patent Application Publication
(10) Pub. No.: US 2023/0352585 A1
(43) Pub. Date: Nov. 2, 2023

(54) DEVICE WITH FERROELECTRIC OR NEGATIVE CAPACITANCE MATERIAL, METHOD OF MANUFACTURING DEVICE WITH FERROELECTRIC OR NEGATIVE CAPACITANCE MATERIAL, AND ELECTRONIC APPARATUS

(71) Applicant: INSTITUTE OF MICROELECTRONICS, CHINESE ACADEMY OF SCIENCES, Beijing (CN)

(72) Inventors: Huilong Zhu, Poughkeepsie, NY (US); Weixing Huang, Beijing (CN)

(21) Appl. No.: 18/042,612

(22) PCT Filed: Mar. 23, 2021
(86) PCT No.: PCT/CN2021/082328

§ 371 Date: Feb. 23, 2023

(30) Foreign Application Priority Data
Sep. 7, 2020 (CN) 202010932063.6

(51) Int. Cl. H01L 29/78; H01L 29/51; H01L 29/40; H01L 29/66

(52) U.S. Cl. CPC H01L 29/78391; H01L 29/516; H01L 29/7851; H01L 29/401; H01L 29/66795; H01L 29/6684; H01L 29/66545

(57) ABSTRACT

Disclosed are a semiconductor device with a ferroelectric or negative capacitance material layer on a sidewall of a gate electrode, a method of manufacturing the semiconductor device, and an electronic apparatus including the semiconductor device. According to embodiments, the semiconductor device may include: a substrate; a gate electrode formed on the substrate; a ferroelectric or negative capacitance material layer formed on a sidewall of the gate electrode; and a source region and a drain region that are located on opposite sides of the gate electrode on the substrate.

### CROSS REFERENCE TO RELATED APPLICATION(S)

This application claims priority to Chinese patent Application No. 202010932063.6, filed on Sep. 7, 2020, entitled “Device with ferroelectric or negative capacitance material, method of manufacturing device with ferroelectric or negative capacitance material, and electronic apparatus”, the entire content of which is incorporated herein in its entirety by reference.

### TECHNICAL FIELD

The present disclosure relates to a technical field of semiconductors, and in particular relates to a semiconductor device with a ferroelectric or negative capacitance material layer on a sidewall of a gate electrode, a method of manufacturing the semiconductor device, and an electronic apparatus including the semiconductor device.

### BACKGROUND

As a density of devices in Integrated Circuit (IC) continually increases, a spacing between components becomes smaller. This increases a fraction of an overlap capacitance between components in the IC, e.g., between a gate electrode and a source/drain, in a total capacitance of a device, and thus degrades an alternating current (AC) performance of the IC. On the other hand, even for a device whose performance requirement is not high, it is desirable to obtain low power consumption and thus reduce capacitance.

### SUMMARY

In view of the above, an objective of the present disclosure is at least in part to provide a semiconductor device with a ferroelectric or negative capacitance material layer on a sidewall of a gate electrode, a method of manufacturing the semiconductor device, and an electronic apparatus including the semiconductor device.

According to an aspect of the present disclosure, there is provided a semiconductor device, including: a substrate; a gate electrode formed on the substrate; a ferroelectric or negative capacitance material layer formed on a sidewall of the gate electrode; and a source region and a drain region that are located on opposite sides of the gate electrode on the substrate.

According to another aspect of the present disclosure, there is provided a method of manufacturing a semiconductor device, including: forming a dummy gate on a substrate; forming a spacer on a sidewall of the dummy gate by using a ferroelectric or negative capacitance material; and removing the dummy gate, and forming a gate electrode in a gate groove formed by a removal of the dummy gate on an inner side of the spacer.

According to another aspect of the present disclosure, there is provided a method for manufacturing a semiconductor device, including: forming a dummy gate on a substrate; forming a spacer on a sidewall of the dummy gate; removing the dummy gate, and forming a ferroelectric or negative capacitance material layer in a gate groove formed by a removal of the dummy gate on an inner side of the spacer; and forming a gate electrode in the gate groove on which the ferroelectric or negative capacitance material layer is formed.

According to another aspect of the present disclosure, there is provided an electronic apparatus, including the semiconductor device described above.

According to embodiments of the present disclosure, a ferroelectric or negative capacitance material layer may be provided on a sidewall of a gate electrode. The ferroelectric or negative capacitance material layer may be in form of a spacer, and therefore may be called a performance enhanced (PE) spacer. By adjusting a material of the ferroelectric or negative capacitance material layer, device characteristics, such as a threshold voltage (Vt), a drain induced barrier lowering (DIBL), a subthreshold swing (SS), etc., may be easily adjusted. For example, due to an introduction of the ferroelectric or negative capacitance material layer, an overlap capacitance between the gate electrode and the source/drain (or a contact portion to the source/drain) may be reduced. Accordingly, a conduction current of the device may be increased, and the subthreshold swing (SS) may be reduced, so as to enhance device performance and reduce power consumption.

### BRIEF DESCRIPTION OF THE DRAWINGS

The above and other objectives, features and advantages of the present disclosure will be more apparent through the following description of embodiments of the present disclosure with reference to the accompanying drawings, in which:

FIG. 1 to FIG. 12(c) schematically show some stages in a process of manufacturing a semiconductor device according to an embodiment of the present disclosure; and

FIG. 13 to FIG. 25 schematically show some stages in a process of manufacturing a semiconductor device according to another embodiment of the present disclosure.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following description, descriptions of well-known structures and technologies are omitted to avoid unnecessarily obscuring the concepts of the present disclosure.

Various schematic structural diagrams according to embodiments of the present disclosure are shown in the accompanying drawings. The figures are not drawn to scale. Some details are enlarged and some details may be omitted for clarity of presentation. The shapes of the various regions and layers as well as the relative size and positional relationship thereof shown in the figures are only exemplary. In practice, there may be deviations due to manufacturing tolerances or technical limitations, and those skilled in the art may additionally design regions/layers with different shapes, sizes and relative positions according to actual needs.

In the context of the present disclosure, when a layer/element is referred to as being “on” a further layer/element, the layer/element may be directly on the further layer/element, or there may be an intermediate layer/element between them. In addition, if a layer/element is located “on” a further layer/element in one orientation, the layer/element may be located “under” the further layer/element when the orientation is reversed.

According to embodiments of the present disclosure, a ferroelectric or negative capacitance material layer may be provided on a sidewall of a gate electrode of a semiconductor device. A ferroelectric material is generally in one of two polarization states, for example, one of an upward polarization or a downward polarization. However, under some special conditions (special matching of capacitance), the ferroelectric material may be stabilized between two polarization states, namely the so-called negative capacitance state. Depending on a state of the ferroelectric or negative capacitance material, the device may have different performances, such as a threshold voltage (Vt), a drain induced barrier lowering (DIBL), a subthreshold swing (SS), etc. When the ferroelectric or negative capacitance material is in the negative capacitance state, a negative capacitance may be introduced between the gate electrode and the source/drain (or a contact portion to the source/drain) (which may lead to a decrease of a total capacitance of the semiconductor device), and may even lead to a total capacitance between the gate and the source/drain being less than zero (which may lead to SS less than 60 mV/dec at 300 K). The technology of the present disclosure may be applied to various semiconductor devices, such as a metal oxide semiconductor field effect transistor (MOSFET), such as a planar MOSFET, a fin field effect transistor (FinFET), a nanowire or a nanosheet FET, etc.

The ferroelectric or negative capacitance material layer may be in form of a spacer. For example, the spacer may be a spacer formed on a dummy gate, so that a gate groove for forming the gate electrode is defined after removing the dummy gate, and a gate dielectric layer and a gate electrode layer may be formed in the gate groove. In addition, other ferroelectric or negative capacitance material layers may also be formed on a sidewall of the gate electrode in the gate groove. Alternatively, the spacer may not be a spacer formed on the dummy gate, but a spacer additionally formed in the gate groove defined after the removal of the dummy gate. The spacer formed on the dummy gate may also include the ferroelectric or negative capacitance material.

That is, the ferroelectric or negative capacitance material layer in form of a spacer may be a gate spacer of the device, and may extend along a substantially entire height of the sidewall of the gate electrode. In the present disclosure, the so-called “substantially entire height” or “a main portion of the height” may mean that the rest portion of the height is occupied by the gate spacer, except for a margin to be considered due to a process fluctuation or some residues in other steps that occupy a small portion of the height.

Alternatively, the ferroelectric or negative capacitance material layer may extend continuously on the sidewall of the gate electrode and a bottom surface of the gate electrode. In this case, the ferroelectric or negative capacitance material layer may be formed in the gate groove defined after the removal of the dummy gate (the spacer including the ferroelectric or negative capacitance material may also be formed on the sidewall). For example, the ferroelectric or negative capacitance material layer may be formed between the gate dielectric layer and the gate electrode, or may be formed between an inner wall of the gate groove and the gate dielectric layer.

In addition, a potential equalization layer may be introduced to equalize a potential on a surface of the gate electrode. For example, the potential equalization layer may be provided between the gate dielectric layer and the ferroelectric or negative capacitance material layer.

Such a semiconductor device may be, for example, manufactured as follows. A dummy gate may be formed on a substrate, and a dummy gate spacer may be formed on a sidewall of the dummy gate. The dummy gate spacer may be single-layer or multi-layer configuration, wherein at least one layer in the dummy gate spacer may be a ferroelectric or negative capacitance material layer. The dummy gate may be removed to form a gate groove on an inner side of the dummy gate spacer. In the gate groove, a ferroelectric or negative capacitance material layer (which may be omitted if the dummy gate spacer includes a ferroelectric or negative capacitance material layer) and a gate electrode layer may be formed. The ferroelectric or negative capacitance material layer formed in the gate groove may be formed as a spacer on a sidewall of the gate groove, or extend continuously along the sidewall of the gate groove and a bottom surface of the gate groove. In addition, an interface layer may be formed on the sidewall of the gate groove and the bottom surface of the gate groove before forming a ferroelectric or negative capacitance material layer in the gate groove.

The present disclosure may be presented in various forms, some examples of which will be described below. In the following description, a selection of various materials is involved. In the selection of materials, in addition to a function of the material (for example, a semiconductor material may be used to form an active region, and a dielectric material may be used to form an electrical isolation), the etching selectivity is also considered. In the following description, the required etching selectivity may or may not be indicated. It should be clear to those skilled in the art that when etching a material layer is mentioned below, if it is not mentioned or shown that other layers are also etched, then the etching may be selective, and the material layer may have an etching selectivity with respect to other layers exposed to the same etching recipe.

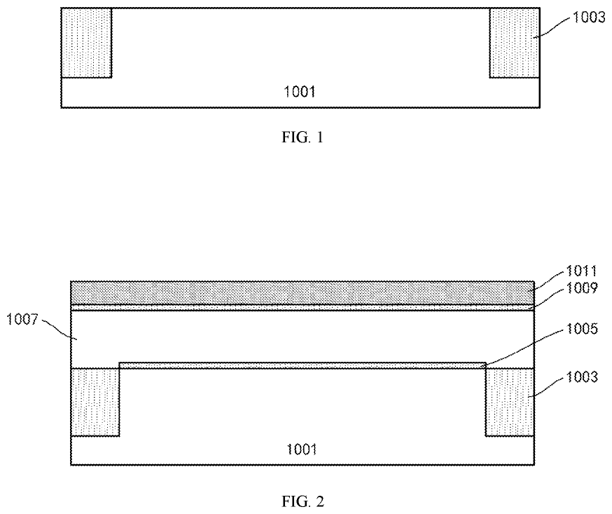

FIG. 1 to FIG. 12(c) schematically show some stages in a process of manufacturing a semiconductor device according to an embodiment of the present disclosure.

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following description, for convenience of explanation, the bulk Si substrate is described as an example. Here, a silicon wafer is provided as the substrate 1001.

On the substrate 1001, a shallow trench isolation (STI) 1003 may be formed to define an active region. For example, the STI 1003 may be formed by trenching in the substrate 1001 and filling the trench with a dielectric such as oxide (for example, silicon oxide). A device may be formed on the active region.

As shown in FIG. 2, a dummy gate dielectric layer 1005 and a dummy gate electrode layer 1007 may be formed on the substrate 1001. For example, the dummy gate dielectric layer 1005 may include an oxide formed by, for example, oxidation or deposition. The dummy gate electrode layer 1007 may include polycrystalline silicon formed by, for example, deposition, with a thickness of about 30 nm to 60 nm. In addition, a hard mask layer 1011 may be provided on the dummy gate electrode layer 1007 for the convenience of patterning. For example, the hard mask layer 1011 may include a nitride (for example, silicon nitride) with a thickness of about 20 nm to 50 nm. Between the dummy gate electrode layer 1007 and the hard mask layer 1011, a cushion layer 1009 such as oxide may further be provided with a thickness of about 10 nm to 20 nm.

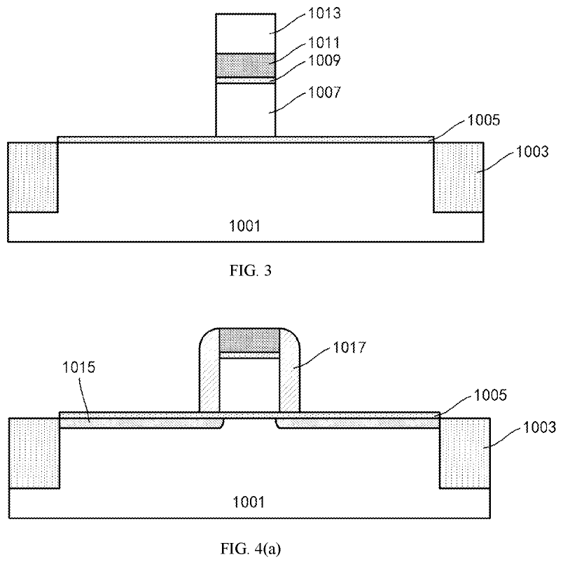

Next, the dummy gate may be patterned. For example, as shown in FIG. 3, a photoresist 1013 may be formed on the hard mask layer 1011, and the photoresist 1013 may be patterned by photolithography into a gate pattern to be formed, such as a strip shape extending in a direction of entering a paper surface in FIG. 3. Then, with the photoresist 1013 as a mask, the hard mask layer 1011, the cushion layer 1009, and the dummy gate electrode layer 1007 are etched in sequence by selective etching, such as reactive ion etching (RIE), so as to form the dummy gate. Here, the RIE may be performed in a vertical direction (a direction substantially perpendicular to a surface of the substrate) and may stop at the dummy gate dielectric layer 1005. Alternatively, the RIE may also be performed on the dummy gate dielectric layer 1005 and may stop on a surface of the substrate 1001. After that, the photoresist 1013 may be removed.

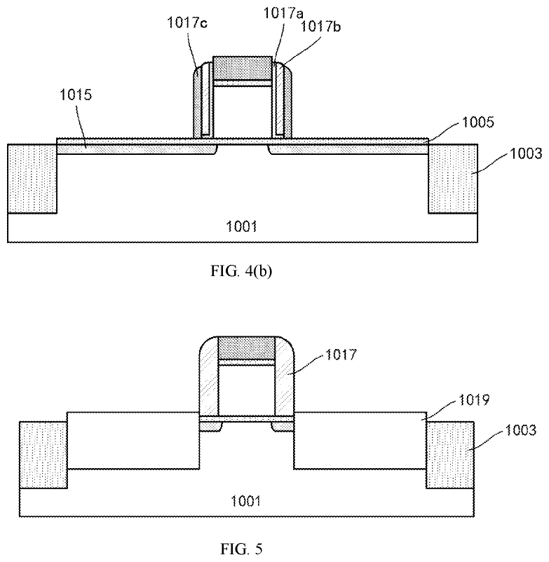

As shown in FIG. 4(a), with the dummy gate as a mask, ion implantation may be performed on the substrate 1001 to form an extension 1015 in the substrate. For example, if an n-type device is to be formed, an n-type impurity such as As or P may be injected. If a p-type device is to be formed, a p-type impurity such as B or BF₂ may be injected. An annealing process (e.g., spike annealing) may be performed at, for example, about 1000° C. to 1080° C. to activate an injected impurity. Due to a tilt angle or scattering during injection, or diffusion during annealing, etc., an edge of the extension 1015 may protrude inward with respect to a sidewall of the dummy gate.

A spacer 1017 may be formed on the sidewall of the dummy gate. For example, a spacer material layer may be deposited on the substrate 1001 on which the dummy gate is formed in a substantially conformal manner by, for example, atomic layer deposition (ALD) or chemical vapor deposition (CVD), and an anisotropic etching, such as RIE in the vertical direction, may be performed on the deposited spacer material layer, to remove a lateral extending portion of the spacer material layer, and (at least partially) leave a vertical extending portion of the spacer material layer, so as to form the spacer.

According to embodiments of the present disclosure, the spacer 1017 may be formed by a ferroelectric or negative capacitance material, with a thickness of, for example, about 1 nm to 50 nm. For example, the ferroelectric or negative capacitance material may include an oxide containing Hf, Zr, Si and/or Al, such as HfZrO.

A ferroelectric material is generally in one of two polarization states, for example, one of an upward polarization or a downward polarization. However, under some special conditions (special matching of capacitance), the ferroelectric material may be stabilized between two polarization states, namely the so-called negative capacitance state (which thus may also be called “negative capacitance material”). Depending on a state of the ferroelectric or negative capacitance material, the device may have different performances, such as a threshold voltage (Vt), a drain induced barrier lowering (DIBL), a subthreshold swing (SS), etc. When the ferroelectric or negative capacitance material is in the negative capacitive state, a negative capacitance may be introduced between the gate electrode and the source/drain. Accordingly, a total capacitance of the semiconductor device may be reduced.

When the ferroelectric material is switched between different polarization states, data may be stored according to different device states such as Vt caused by different polarization states. For example, when a capacitance value between the gate electrode and the source or drain region is less than zero, or a stable state may only be one of the polarization states, thus the semiconductor device may be used in a memory device. In addition, when the ferroelectric material is stabilized between two polarization states (in a stable negative capacitance), the resulting negative capacitance value may reduce an overlap capacitance in the device, and thus improve the device performance, thus the semiconductor device may be used in a logic device. In particular, when an absolute value of negative capacitance value caused by the ferroelectric or negative capacitance material is greater than a sum of a capacitance between the gate electrode and the source electrode and a capacitance between the gate electrode and the drain electrode, the negative capacitance value caused by the ferroelectric or negative capacitance material may even lead to SS less than 60 mV/dec at a temperature of 300 K.

In an example of FIG. 4(a), a single-layer spacer configuration is shown. However, the present disclosure is not limited to this. For example, the spacer may have a multi-layer configuration, wherein one or more layer may be formed by the ferroelectric or negative capacitance material.

For example, as shown in FIG. 4(b), an oxide layer of about 1 nm to 3 nm and a ferroelectric or negative capacitance material layer of about 1 nm to 50 nm may be deposited in a substantially conformal manner by CVD or ALD, or the like. Anisotropic etching such as RIE may be performed on the ferroelectric or negative capacitance material layer to obtain a spacer 1017b. With the spacer 1017b as a mask, selective etching such as RIE may be performed on the oxide layer 1017a to obtain the spacer 1017a. The spacer 1017a may be L-shaped. Then, a nitride layer of about 1 nm to 5 nm may be deposited in a substantially conformal manner by CVD or ALD, or the like, and anisotropic etching such as RIE may be performed on the nitride layer to obtain a spacer 1017c. The spacer 1017c may protect the spacer 1017b of the ferroelectric or negative capacitance material. Through the multi-layer configuration, a capacitance caused by the spacer may be adjusted.

Those skilled in the art know various ways to form spacers of various configurations, and the above are merely examples. In the following description, for convenience, the description will be made mainly by taking the configuration shown in FIG. 4(a) as an example. However, the example described below is also applicable to the spacer configuration shown in FIG. 4(b) or other spacer configurations.

After the spacer 1017 is formed, a source/drain region may be formed by performing ion implantation on the substrate 1001 by using the dummy gate and the spacer 1017 as masks. According to the embodiment, the strain source/drain technology may be adopted to further improve the performance. For example, as shown in FIG. 5, the dummy gate and the spacer 1017 may be used as masks to perform selective etching such as RIE on (the dummy gate dielectric layer 1005 and) the substrate 1001, so as to form a groove in the substrate 1001 on two sides of the dummy gate. In the groove of the substrate 1001, a source/drain layer 1019 may be formed by, for example, epitaxial growth. The source/drain layer 1019 may include a semiconductor material with a lattice constant different from a lattice constant of the substrate 1001, thereby generating strain to apply a stress to a channel region (a portion below the dummy gate) in the substrate 1001, so as to improve carrier mobility. For example, for a p-type device, the source/drain layer 1019 may include a semiconductor material such as SiGe (an atomic percentage of Ge is about 20% to 70%) with a lattice constant greater than the lattice constant of the substrate 1001 (Si in this example), so as to generate a compressive stress; and for an n-type device, the source/drain layer 1019 may include a semiconductor material such as Si:C (an atomic percentage of C is about 0.01% to 2%) with a lattice constant less than the lattice constant of the substrate 1001 (Si in this example), so as to generate a tensile stress. The source/drain layer 1019 may be in-situ doped to a conductive type identical to a conductive type of the device to be formed when growing, so as to form a source/drain region in the source/drain layer 1019. In addition, a surface of the source/drain layer 1019 may be higher than a surface of the substrate 1001, so as to improve a stress application effect.

Next, a gate replacement process may be performed, so as to replace the dummy gate by a final gate stack.

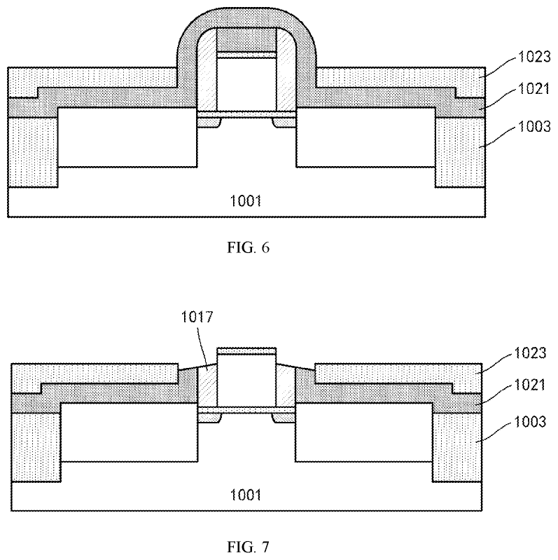

As shown in FIG. 6, for a purpose of stress enhancement, a liner layer 1021 may be formed by, for example, deposition. For example, the liner layer 1021 may include a nitride, with a thickness of about 10 nm to 20 nm. On the liner layer 1021, an interlayer dielectric layer 1023, such as an oxide, may be formed by, for example, deposition. For example, an oxide of about 100 nm to 150 nm may be deposited, and the deposited oxide may be subjected to a planarization process, such as chemical mechanical polishing (CMP), and the CMP may stop at the liner layer 1021. In addition, the planarized oxide may be etched back, so that the dummy gate may be better exposed subsequently to perform the gate replacement process.

As shown in FIG. 7, the liner layer 1021 may be etched by selectively etching, such as RIE. In this example, since the hard mask layer 1011 and the liner layer 1021 are both nitrides, the hard mask layer 1011 may also be etched. Accordingly, the dummy gate may be exposed. In addition, a height of the spacer 1017 may be reduced during etching.

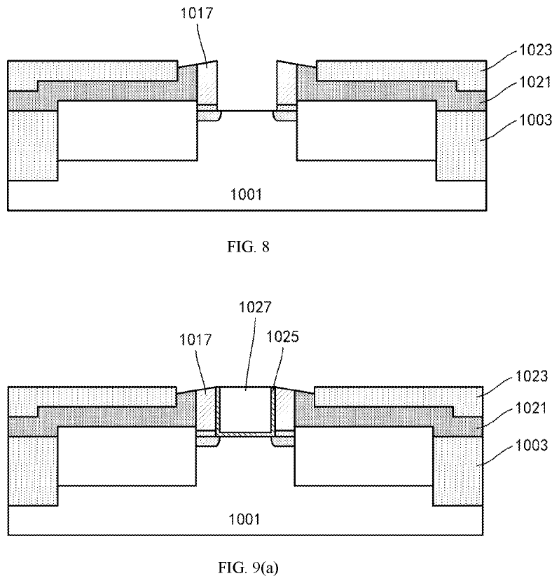

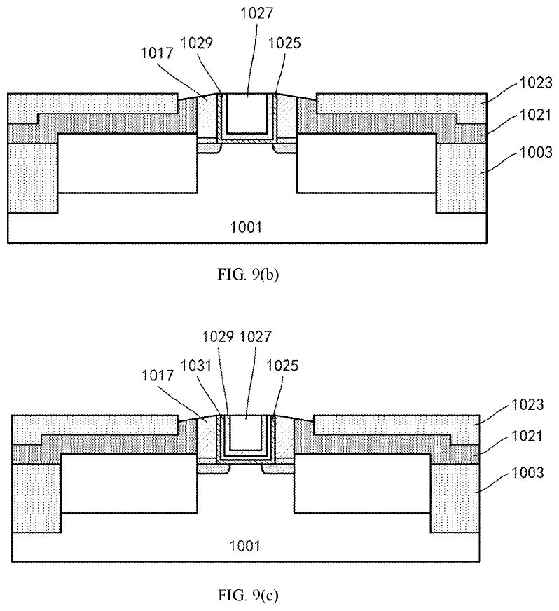

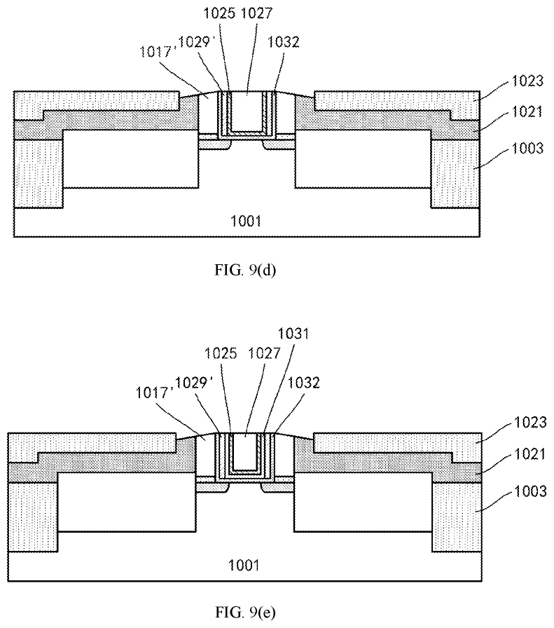

As shown in FIG. 8, the cushion layer 1009, the dummy gate electrode layer 1007, and the dummy gate dielectric layer 1005 may be etched in sequence by selective etching such as RIE, so as to form a gate groove on an inner side of the spacer 1017. A gate stack may be formed in the gate groove. For example, as shown in FIG. 9(a), a gate dielectric layer 1025 and a gate electrode layer 1027 may be deposited sequentially, and the deposited gate dielectric layer 1025 and gate electrode layer 1027 may be etched back, so as to leave the gate dielectric layer 1025 and the gate electrode layer 1027 in the gate groove. For example, the gate dielectric layer 1025 may include a high-k gate dielectric such as HfO₂, with a thickness of about 2 nm to 10 nm. The gate electrode layer 1027 may include a work function adjustment layer such as TiN, TiAlN, TaN, etc. and a gate conductor layer such as W, Co, Ru, etc. Before forming the high-k gate dielectric, an interface layer may also be formed, such as an oxide formed by an oxidation process or a deposition such as ALD, with a thickness of about 0.3 nm to 2 nm. In this way, the spacer 1017 formed by the ferroelectric or negative capacitance material is provided on a sidewall of the gate stack (1025/1027).

According to another embodiment of the present disclosure, as shown in FIG. 9(b), a ferroelectric or negative capacitance material layer 1029 may be provided between the gate dielectric layer 1025 and the gate electrode layer 1027. For example, the gate dielectric layer 1025, the ferroelectric or negative capacitance material layer 1029 and the gate electrode layer 1027 may be sequentially deposited in the gate groove (an interface layer may be formed on a surface of the gate groove), and may be left in the gate groove by etching back. The ferroelectric or negative capacitance material layer 1029 may include a material identical to or different from a material of the spacer 1017, with a thickness of, for example, about 2 nm to 20 nm. Through the ferroelectric or negative capacitance material layer 1029, the capacitance may be further adjusted, for example, to cause an absolute value of the negative capacitance to be greater.

In addition, when a ferroelectric or negative capacitance material layer is additionally formed in the gate groove, the spacer 1017 may be composed of the ferroelectric or negative capacitance material as described above, or the spacer 1017 may also be composed of the dielectric material as the conventional spacer.

In addition, when the ferroelectric or negative capacitance material layer 1029 is provided, as shown in FIG. 9(c), a potential equalization layer 1031 may further be provided between the gate dielectric layer 1025 and the ferroelectric or negative capacitance material layer 1029. For example, the potential equalization layer 1031 may include a conductive material containing at least one of Ti, Ru, Co and Ta, such as TiN, with a thickness of about 0.5 nm to 3 nm, which is used to equalize a potential on an interface between the gate dielectric layer 1025 and the ferroelectric or negative capacitance material layer 1029.

In the example of FIG. 9(a) and FIG. 9(b), the ferroelectric or negative capacitance material layer 1029 is formed along a sidewall of the gate electrode layer 1027 and a bottom surface of the gate electrode layer 1027, and thus exists between the bottom surface of the gate electrode layer 1027 and the substrate 1001. That is, the gate electrode layer 1027 controls the channel region in the substrate 1001 by the ferroelectric or negative capacitance material layer 1029 and the gate dielectric layer 1025 (and the interface layer). However, the present disclosure is not limited to this. The ferroelectric or negative capacitance material layer 1029 may also be formed in form of spacer.

For example, as shown in FIG. 9(d), on the sidewall of the spacer, a spacer 1029′ of the ferroelectric or negative capacitance material may be formed through a spacer forming process, with a thickness of, for example, about 2 nm to 20 nm. In addition, before forming the spacer 1029′, an interface layer 1032 such as oxide with a thickness of about 0.3 nm to 2 nm may further be formed by deposition. In the gate groove in which the spacer 1029′ is formed, the gate stack 1025/1027 may be formed. In this case, the previously formed spacer may be composed of the ferroelectric or negative capacitance material described above, or may also be composed of the dielectric material as the conventional spacer, which is labeled as 1017′ here. In this example, the spacer of the ferroelectric or negative material is formed after the formation of the gate groove, which is beneficial to protect the spacer of the ferroelectric or negative capacitance material from an influence of high temperature treatment such as source/drain layer growth and annealing process in a front-end process. In this case, the gate electrode layer 1027 controls the channel region in the substrate 1001 by the gate dielectric layer 1025 (and the interface layer 1032), similar to a case of conventional gate stack. In addition, since the spacer 1029′ is provided, the extension 1015 may extend inwards beyond the spacer 1029′.

In addition, in a case of providing the spacer 1029′ of the ferroelectric or negative capacitance material, similarly, as shown in FIG. 9(e), the potential equalization layer 1031 may further be provided on the sidewall of the gate electrode layer 1027 and the bottom surface of the gate electrode layer 1027. For example, the potential equalization layer 1031 may include a conductive material such as TiN, with a thickness of about 0.5 nm to 3 nm, which is used to equalize a potential on the sidewall of the gate electrode layer 1027 and the bottom surface of the gate electrode layer 1027.

So far, the device has been substantially completed. A contact portion and an interconnection may be fabricated.

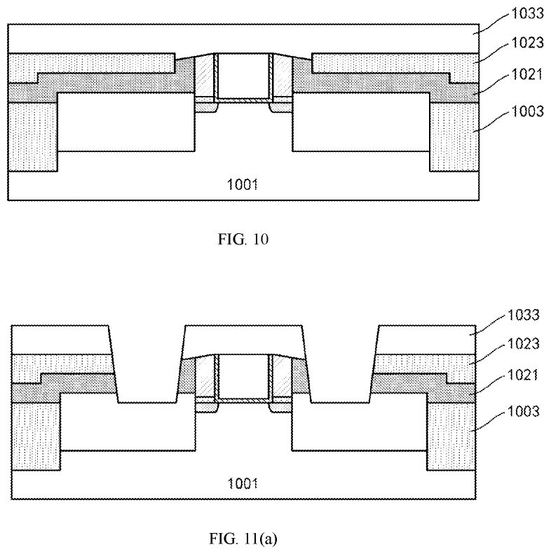

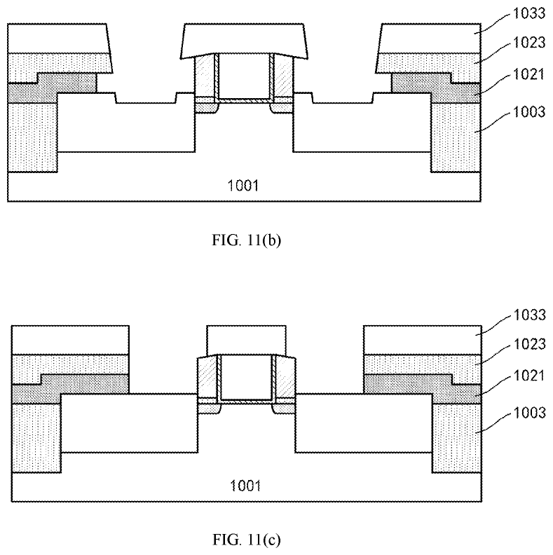

For example, as shown in FIG. 10, a dielectric such as SiC may be deposited and planarized such as CMP, so as to form a dielectric layer 1033. Then, a hole may be opened in each dielectric layer on the source/drain layer and filled with a conductive material such as metal to form the contact portion. There may be a plurality of opening modes. For example, as shown in FIG. 11(a), a photoresist (not shown) may be formed on the dielectric layer 1033 and the photoresist may be patterned to expose a region where the contact portion needs to be formed. With the patterned photoresist as a mask, the dielectric layer 1033, the interlayer dielectric layer 1023 and the liner layer 1021 are etched by selective etching such as RIE, so as to form a contact hole to expose the source/drain layer 1019 below. In this example, the contact hole is tapered from top to bottom and separated from the spacer 1017. According to another embodiment, as shown in FIG. 11(b), after the contact hole shown in FIG. 11(a) is formed, the liner layer 1021 may be further selectively etched, and the selective etching may stop at the spacer 1017 to expose the spacer 1017. Accordingly, the conductive material subsequently filled in the contact hole may be in directly contact with the spacer 1017, so as to better control a capacitance between the gate stack and the contact portion. According to another embodiment, as shown in FIG. 11(c), the photoresist is patterned to overlap with the spacer 1017, so that at least a part of a boundary of the contact hole obtained by using the photoresist as a mask is defined by the spacer 1017 (also known as the contact hole self-aligning to the spacer 1017). In this case, an etching parameter may be controlled so that the etching may obtain a basically vertical feature. Similarly, the conductive material subsequently filled in the contact hole may be in directly contact with the spacer 1017, so as to better control the capacitance between the gate stack and the contact portion.

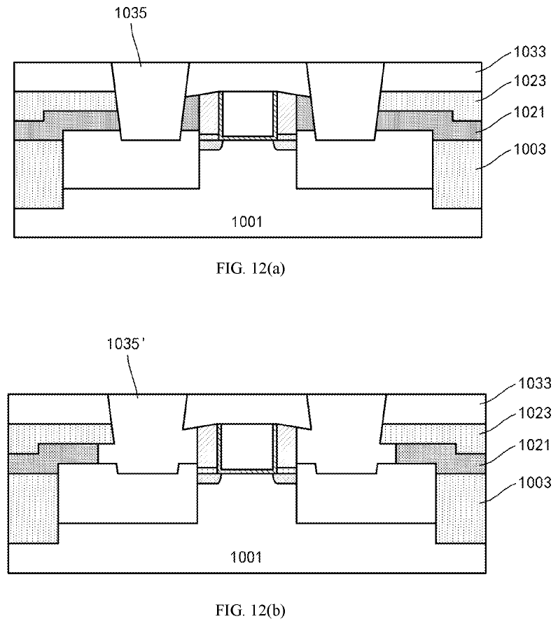

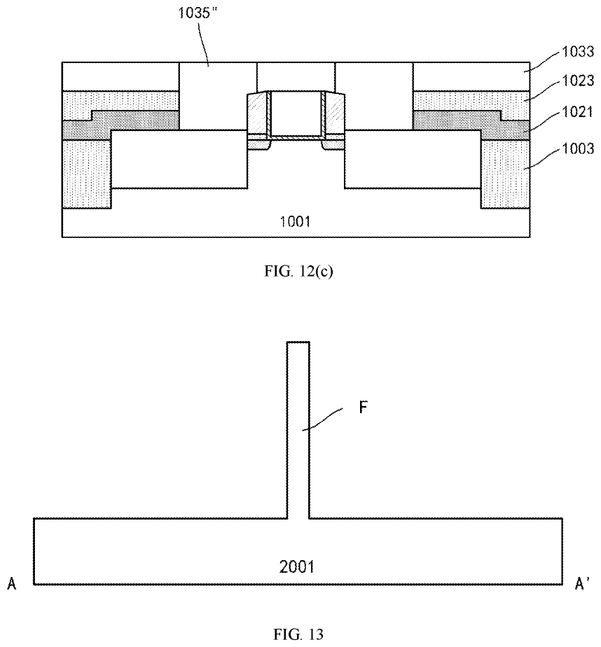

Then, as shown in FIG. 12(a), FIG. 12(b) and FIG. 12(c) respectively, contact holes shown in FIG. 11(a), FIG. 11(b) and FIG. 11(c) are filled with a conductive material such as metal W or Co, so as to form contact portions 1035, 1035′ and 1035″ respectively. It may be seen that the spacer 1017 formed by the ferroelectric or negative capacitance material (and/or the ferroelectric or negative capacitance material layer 1029, and the spacer 1029′ of the ferroelectric or negative capacitance material) may be located between the gate stack and the contact portion, resulting in a negative capacitance between the gate and the source/drain. This may increase a conduction current of the device, reduce the subthreshold swing (SS), so as to enhance device performance and reduce power consumption.

Examples of a planar MOSFET are described above. The technology of the present disclosure may further be applied to other devices, such as FinFET.

FIG. 13 to FIG. 25 schematically show some stages in a process of manufacturing a semiconductor device according to another embodiment of the present disclosure.

As shown in FIG. 13, a substrate 2001 such as a silicon wafer may be provided, and a fin F may be formed on the substrate 2001. In this example, the fin F may be formed by etching the substrate 2001. However, the present disclosure is not limited to this. For example, a fin material layer may be epitaxially grown on the substrate 2001, and the fin material layer may be etched to form the fin F.

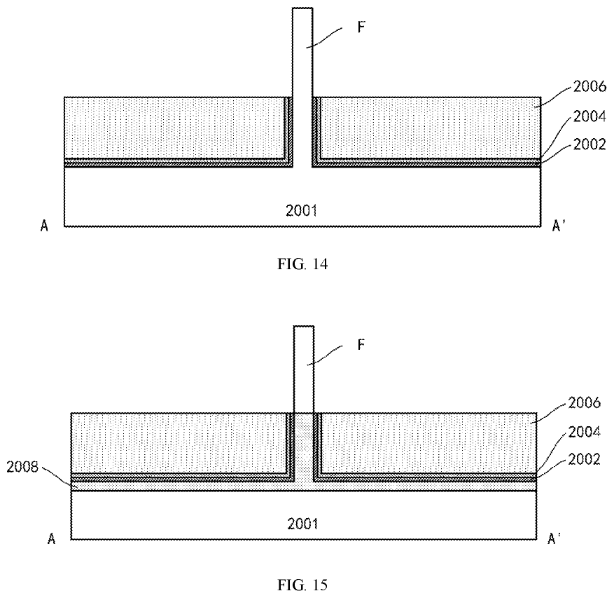

In order to isolate a subsequently formed gate stack from the substrate 2001, as shown in FIG. 14, an isolation layer 2006 may be formed around the fin F on the substrate 2001. For example, the isolation layer 2006 may include an oxide around a bottom portion of the fin F. In addition, in order to suppress a leakage between the source and the drain through the bottom portion of the fin F (a portion of the fin F surrounded by the isolation layer 2006), a punch through stopper (PTS) may be formed. According to embodiments of the present disclosure, the PTS may be formed by diffusion. To this end, a solid phase dopant source layer 2002 may be formed at the bottom portion of the fin F. For example, the solid phase dopant source layer 2002 may be an oxide containing a dopant, with a thickness of about 1 nm to 5 nm. The dopant contained in the solid phase dopant source layer 2002 may have a conductive type opposite to a conductive type of the device to be formed. In addition, a diffusion barrier layer 2004 may be formed on the solid phase dopant source layer 2002, so as to suppress unnecessary diffusion. For example, the diffusion barrier layer 2004 may include a nitride. For example, a solid phase dopant source material layer and a diffusion barrier material layer may be formed sequentially in a substantially conformal manner by, for example, deposition, and an isolation material layer may be deposited. The isolation material layer may be subjected to a planarization process such as CMP and etched back, so as to obtain the isolation layer 2006. The isolation layer 2006 may be used as a mask to perform selective etching such as RIE on the diffusion barrier material layer and the solid phase dopant source material layer, so as to obtain the diffusion barrier layer 2004 and the solid phase dopant source layer 2002.

The formation of the solid phase dopant source layer 2002 is not limited to the deposition of a further material layer. For example, a conformal doping layer may be formed on a surface of the fin F by ion implantation. In addition, after the isolation layer 2006 is formed, the fin F may be etched back to remove a dopant layer formed on a surface of a portion of the fin F above a top surface of the isolation layer 2006.

The dopant contained in the solid phase dopant source layer 2002 may be driven into the bottom portion of the fin F through annealing process to form a PTS 2008, as shown in FIG. 15.

On the isolation layer 2006, a gate stack may be formed. The formation of the gate stack may be performed similarly to the above-mentioned embodiments. For example, the gate replacement process may be used to first form the dummy gate and the spacer on the sidewall of the dummy gate (which may be formed by the ferroelectric or negative capacitance material), and then remove the dummy gate and replace the dummy gate by the gate stack. The ferroelectric or negative capacitance material layer or the spacer of the ferroelectric or negative capacitance material may further be formed on an inner side of the spacer after removing the dummy gate. In summary, a ferroelectric or negative capacitance material is formed on a sidewall of the gate stack, and the ferroelectric or negative capacitance material may be provided by at least one of a spacer formed on the sidewall of the dummy gate, a further spacer formed on the inner side of the spacer, or the ferroelectric or negative capacitance material layer.

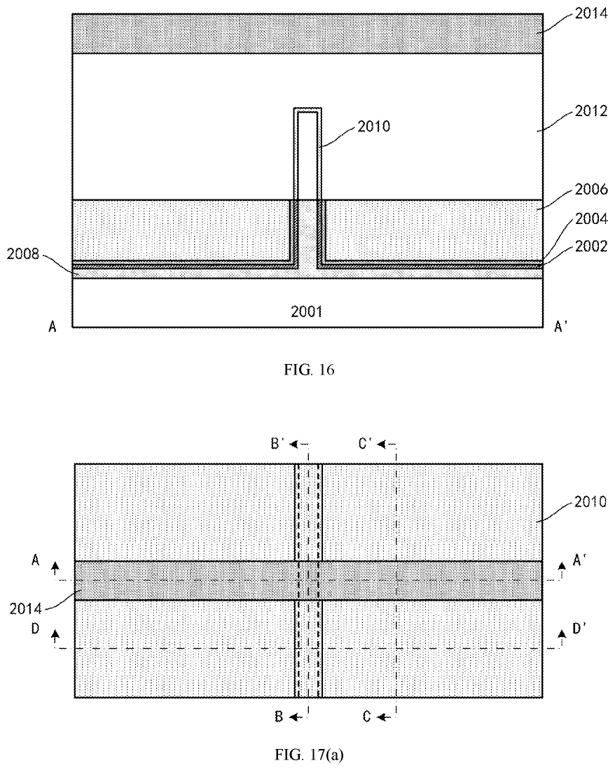

For example, as shown in FIG. 16, a dummy gate dielectric layer 2010 and a dummy gate electrode layer 2012 may be formed on the isolation layer 2006. For example, the dummy gate dielectric layer 2010 may include an oxide or a nitride formed by, for example, oxidation or deposition. The dummy gate electrode layer 2012 may include polycrystalline silicon formed by, for example, deposition followed by planarization such as CMP. On the dummy gate electrode layer 2012, a hard mask layer 2014 such as nitride may be provided.

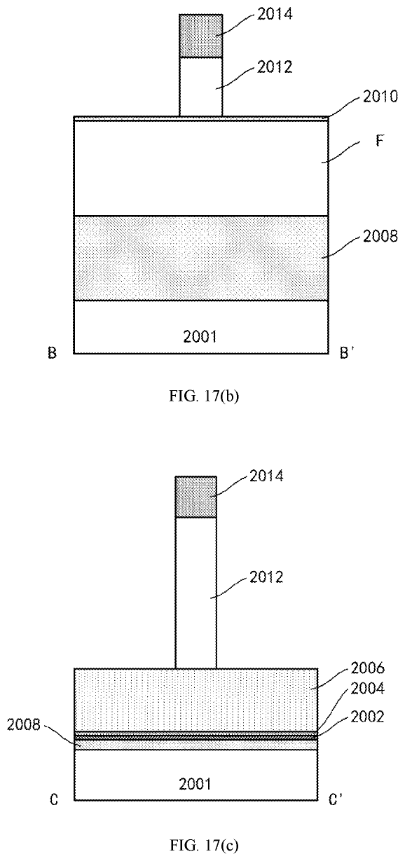

Next, the dummy gate may be patterned. For example, as shown in FIG. 17(a), FIG. 17(b) and FIG. 17(c) (FIG. 17(a) is a top view, showing sectional intercepting positions AA′, BB′, CC′ and DD′, FIG. 17(b) is a section view along line BB′, and FIG. 17(c) is a section view along line CC′), the hard mask layer 2014 and the dummy gate electrode layer 2012 are etched by selective etching such as RIE, so as to pattern the hard mask layer 2014 and the dummy gate electrode layer 2012 as a dummy gate intersecting (for example, perpendicular to) the fin F.

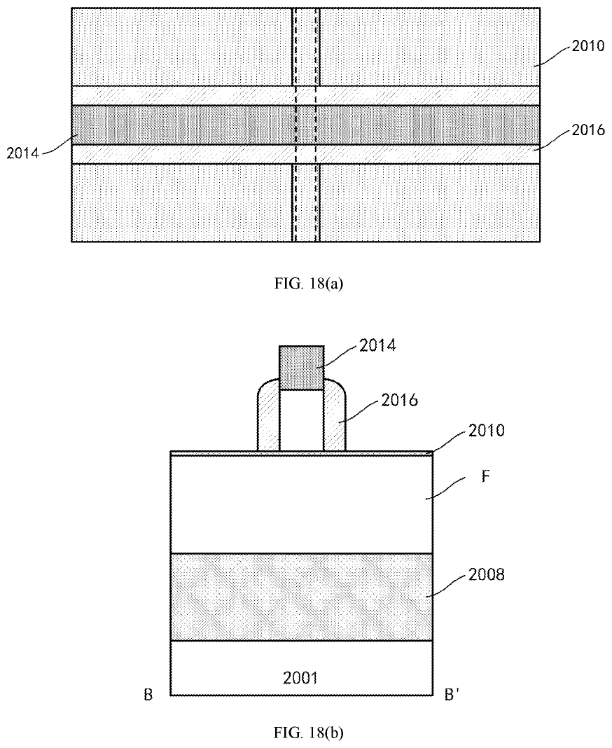

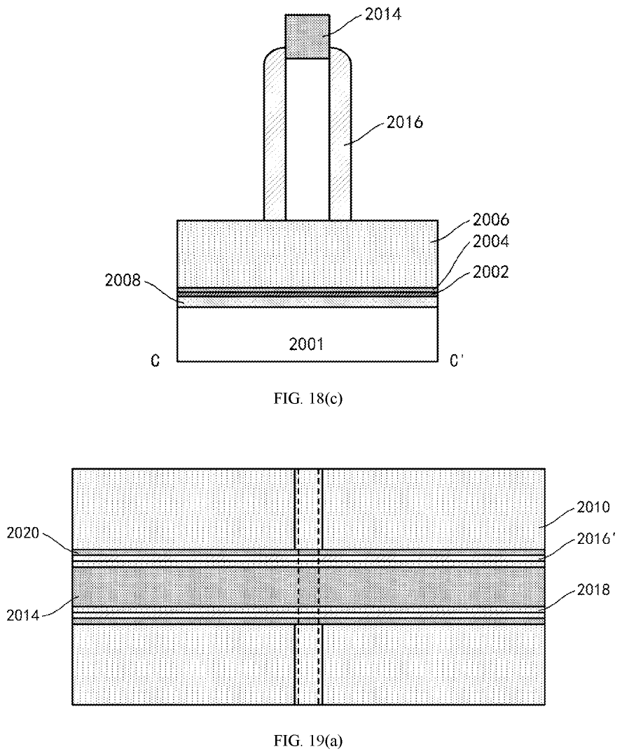

As shown in FIG. 18(a), FIG. 18(b) and FIG. 18(c) (FIG. 18(a) is a top view, FIG. 18(b) is a sectional view along line BB′, and FIG. 18(c) is a sectional view along line CC′), a spacer 2016 may be formed on the sidewall of the dummy gate. By adjusting at least one of a height of a portion of the fin F exposed above the top surface of the isolation layer 2006 and a height of the dummy gate, the spacer 2016 may be formed on the sidewall of the dummy gate instead of on the sidewall of the fin F. The spacer 2016 may be formed of the ferroelectric or negative capacitance material, with a thickness of, for example, about 2 nm to 20 nm.

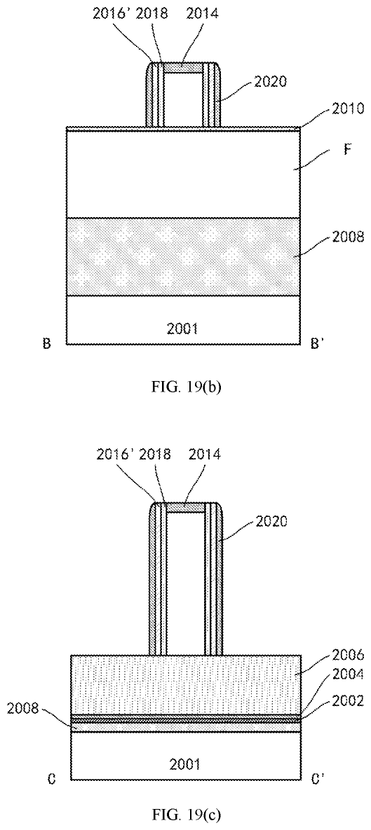

Similarly, a multi-layer spacer configuration may also be formed. For example, as shown in FIG. 19(a), FIG. 19(b) and FIG. 19(c) (FIG. 19(a) is a top view, FIG. 19(b) is a sectional view along line BB′, and FIG. 19(c) is a sectional view along line CC′), spacers 2018, 2016′ and 2020 may be formed on the sidewall of the dummy gate. For the multi-layer spacer configuration, please refer to the above description in combination with FIG. 4(b), which will not be repeated here. In addition, in this example, if the spacer 2020 is nitride, a thickness of the hard mask layer 2014, which is also nitride, is reduced when the spacer 2020 is formed.

In the following description, description will be made mainly with reference to the configuration shown in FIG. 18(a), FIG. 18(b) and FIG. 18(c) as an example. However, the example described below is also applicable to spacer configurations shown in FIG. 19(a), FIG. 19(b) and FIG. 19(c) or other spacer configurations.

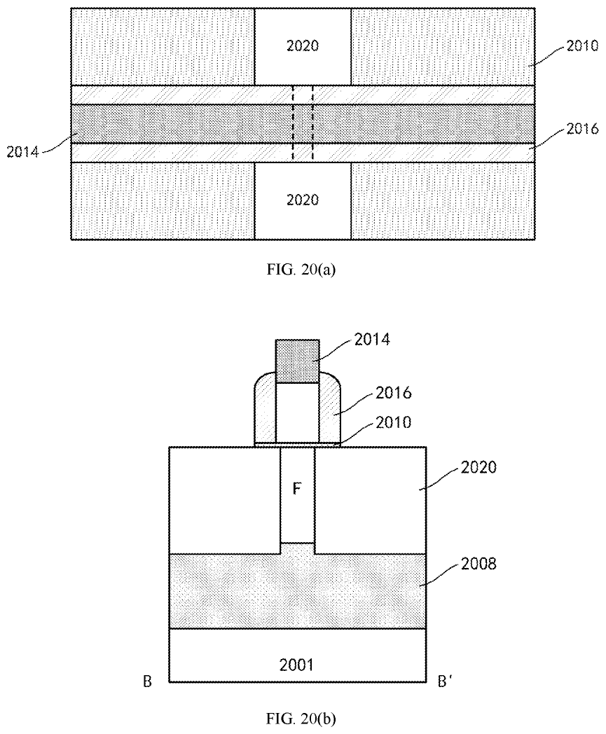

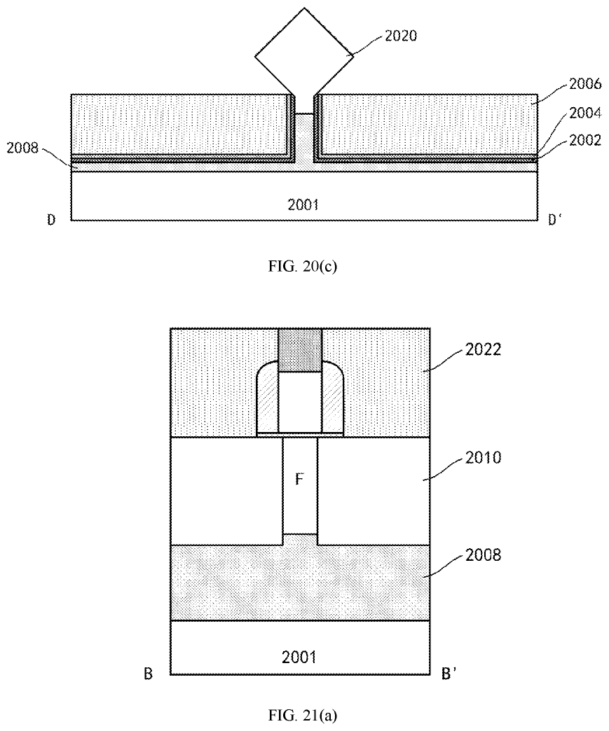

Similarly, the strain source/drain technology may be adopted. For example, as shown in FIG. 20(a), FIG. 20(b) and FIG. 20(c) (FIG. 20(a) is a top view, FIG. 20(b) is a sectional view along line BB′, and FIG. 20(c) is a sectional view along line DD′), the dummy gate and the spacer 2016 may be used as masks to perform selective etching such as RIE on (the dummy gate dielectric layer 2010 and) the fin F, and etching may enter the PTS 2008. An exposed surface of the fin F may be used as a seed to form a source/drain layer 2020 by, for example, epitaxial growth. For details of the source/drain layer 2020, please refer to the above description in combination with FIG. 5.

Next, the gate replacement process may be performed to replace the dummy gate by the final gate stack.

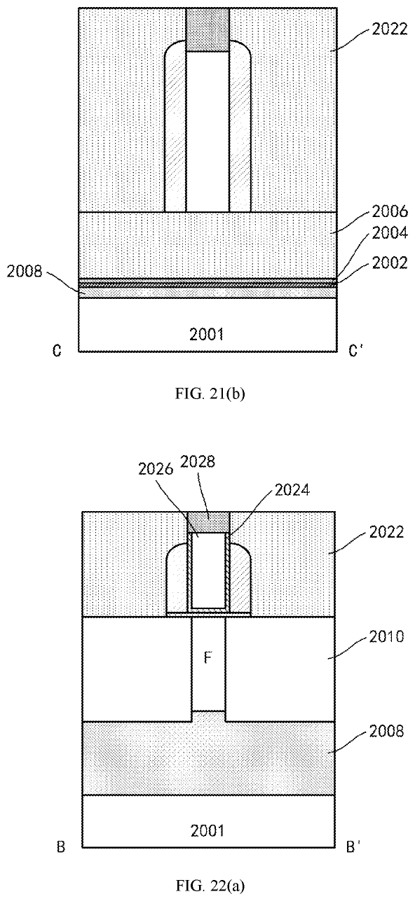

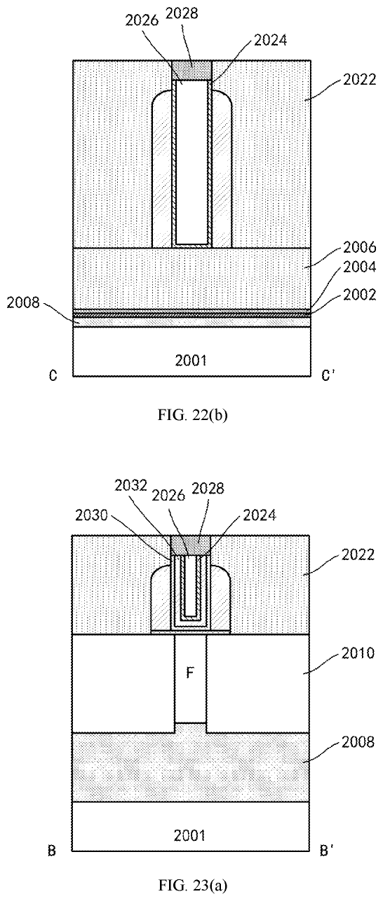

As shown in FIG. 21(a) and FIG. 21(b) (sectional views along line BB′ and line CC′ respectively), an interlayer dielectric layer 2022 such as oxide may be formed on the isolation layer 2006. The interlayer dielectric layer 2022 may be planarized by, such as CMP, and the CMP may stop at the hard mask layer 2014. Then, as shown in FIG. 22(a) and FIG. 22(b) (sectional views along line BB′ and line CC′ respectively), the hard mask layer 2014, the dummy gate electrode layer 2012 and the dummy gate dielectric layer 2010 may be removed by selective etching such as RIE, and a gate dielectric layer 2024 and a gate electrode layer 2026 may be formed in the resulting gate groove. For the gate dielectric layer 2024 and the gate electrode layer 2026, please refer to the above description in combination with FIG. 8. In addition, the gate dielectric layer 2024 and the gate electrode layer 2026 may be etched back, and a cap layer 2028 such as nitride may be formed on top portions of the gate dielectric layer 2024 and the gate electrode layer 2026.

Similarly, the ferroelectric or negative capacitance material layer or the spacer of the ferroelectric or negative capacitance material may also be formed in the gate groove.

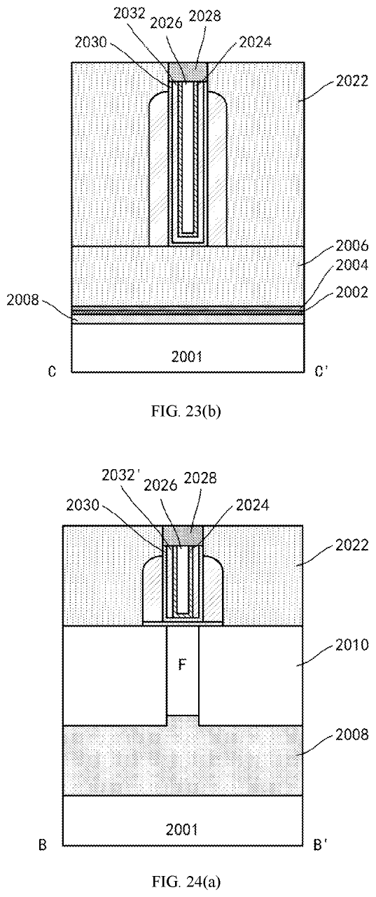

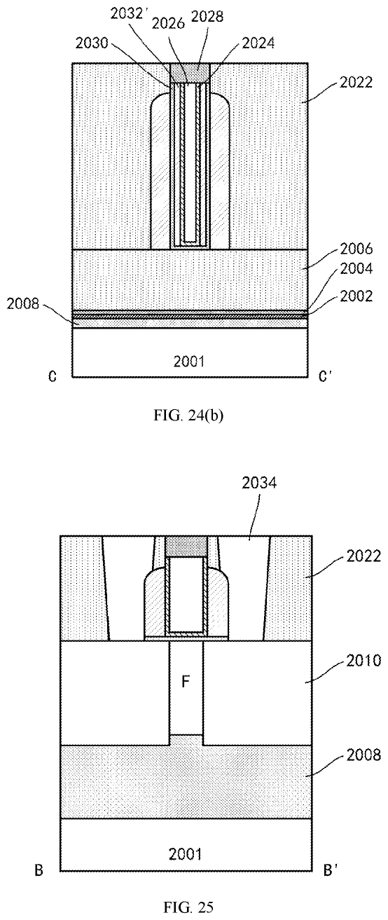

For example, as shown in FIG. 23(a) and FIG. 23(b) (sectional views along line BB′ and line CC′ respectively), a ferroelectric or negative capacitance material layer 2032 may be formed in a substantially conformal manner in the gate groove, and then a gate stack may be formed on the ferroelectric or negative capacitance material layer 2032. Accordingly, the ferroelectric or negative capacitance material layer 2032 may extend along a sidewall of the gate dielectric layer 2024 and a bottom surface of the gate dielectric layer 2024. In addition, an interface layer 2030 such as oxide may be formed before forming the ferroelectric or negative capacitance material layer 2032. In addition, the ferroelectric or negative capacitance material layer 2032′ may also be formed in form of a spacer, as shown in FIG. 24(a) and FIG. 24(b) (sectional views along line BB′ and line CC′ respectively). The various configurations described above in combination with FIG. 9(a) to FIG. 9(e) are also applicable here.

Next, as shown in FIG. 25, a contact portion 2034 may be formed. For the formation of the contact portion, please refer to the above description in combination with FIG. 11(a) to FIG. 12(c).

The semiconductor device according to embodiments of the present disclosure may be applied to various electronic apparatuses. For example, an integrated circuit (IC) may be formed based on such a semiconductor device, and an electronic apparatus may be constructed thereby. Accordingly, the present disclosure further provides an electronic apparatus including the semiconductor device described above. The electronic apparatus may further include a display screen matched with the integrated circuit, a wireless transceiver matched with the integrated circuit, and other components. The electronic apparatus may include, for example, a smart phone, a computer, a personal computer (PC), a wearable intelligent device, a mobile power supply, and so on.

According to embodiments of the present disclosure, a method of manufacturing a system on chip (SoC) is further provided, which may include the method described above. Specifically, a variety of devices may be integrated on a chip, at least some of which are manufactured according to the method of the present disclosure.

In the above description, the technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

1. A semiconductor device, comprising:
a substrate;
a gate electrode formed on the substrate;
a ferroelectric or negative capacitance material layer formed on a sidewall of the gate electrode; and
a source region and a drain region that are located on opposite sides of the gate electrode on the substrate.

2. The semiconductor device according to claim 1, wherein the ferroelectric or negative capacitance material layer is a gate spacer of the semiconductor device.

3. The semiconductor device according to claim 2, wherein the ferroelectric or negative capacitance material layer extends along a substantially entire height of the sidewall of the gate electrode.

4. The semiconductor device according to claim 2, further comprising:
a gate dielectric layer formed on the sidewall of the gate electrode and a bottom surface of the gate electrode,
wherein the gate dielectric layer is located between the gate electrode layer and the ferroelectric or negative capacitance material layer, and the ferroelectric or negative capacitance material layer extends along a main portion of a height of a sidewall of the gate dielectric layer.

5. The semiconductor device according to claim 2, wherein a plurality layers of spacers are formed on the sidewall of the gate electrode, and the ferroelectric or negative capacitance material layer is one of the plurality layers of spacers.

6. The semiconductor device according to claim 5, wherein the plurality layers of spacers comprise:
a L-shaped first dielectric spacer formed on the sidewall of the gate electrode;
the ferroelectric or negative capacitance material layer formed on the L-shaped first dielectric spacer; and
a second dielectric spacer formed on a sidewall of the ferroelectric or negative capacitance material layer.

7. The semiconductor device according to claim 6, wherein the ferroelectric or negative capacitance material layer extends along a substantially entire height of a sidewall of the L-shaped first dielectric spacer.

8. The semiconductor device according to claim 2, further comprising:
an interface layer formed on a sidewall of the ferroelectric or negative capacitance material layer, a bottom surface of the ferroelectric or negative capacitance material layer, and a bottom surface of the gate electrode.

9. The semiconductor device according to claim 2, further comprising:
a further spacer formed on a sidewall of the ferroelectric or negative capacitance material layer facing away from the gate electrode.

10. The semiconductor device according to claim 9, further comprising:
a gate dielectric layer formed on the sidewall of the gate electrode and a bottom surface of the gate electrode,
wherein the ferroelectric or negative capacitance material layer is formed on a sidewall of the gate dielectric layer facing away from the gate electrode and extends along a substantially entire height of a sidewall of the gate dielectric layer.

11. The semiconductor device according to claim 10, further comprising:
a potential equalization layer formed on the sidewall of the gate dielectric layer and a bottom surface of the gate dielectric layer, wherein the potential equalization layer is located between the gate dielectric layer and the ferroelectric or negative capacitance material layer.

12. The semiconductor device according to claim 1, wherein the ferroelectric or negative capacitance material layer extends continuously on the sidewall of the gate electrode and a bottom surface of the gate electrode.

13. The semiconductor device according to claim 12, further comprising:
a gate dielectric layer formed on the sidewall of the gate electrode and the bottom surface of the gate electrode,
wherein the ferroelectric or negative capacitance material layer is located between the gate dielectric layer and the gate electrode.

14. The semiconductor device according to claim 13, further comprising:
a potential equalization layer formed on a bottom surface of the ferroelectric or negative capacitance material layer and a sidewall of the ferroelectric or negative capacitance material layer, wherein the potential equalization layer is located between the ferroelectric or negative capacitance material layer and the gate dielectric layer.

15. The semiconductor device according to claim 12, further comprising:
a gate dielectric layer formed on the sidewall of the gate electrode and the bottom surface of the gate electrode,
wherein the gate dielectric layer is located between the ferroelectric or negative capacitance material layer and the gate electrode.

16. The semiconductor device according to claim 12, further comprising:
a further spacer formed on a sidewall of the ferroelectric or negative capacitance material layer facing away from the gate electrode.

17. The semiconductor device according to claim 9, wherein the further spacer comprises a ferroelectric or negative capacitance material.

18. The semiconductor device according to claim 11, wherein the potential equalization layer is a conductive layer comprising at least one of Ti, Ru, Co and Ta.

19. The semiconductor device according to claim 1, wherein the ferroelectric or negative capacitance material comprises an oxide containing Hf, Zr, Si and/or Al.

20. The semiconductor device according to claim 1, further comprising:
a contact portion to the source region and the drain region respectively,
wherein the ferroelectric or negative capacitance material layer is located between the contact portion and the gate stack.

21. The semiconductor device according to claim 20, wherein a boundary of the contact portion is at least partially defined by a sidewall of the ferroelectric or negative capacitance material layer.

22. The semiconductor device according to claim 1, wherein the semiconductor device is a metal oxide semiconductor field effect transistor (MOSFET).

23. The semiconductor device according to claim 1, wherein a capacitance value between the gate electrode and the source region or the drain region is less than zero.

24. The semiconductor device according to claim 1, wherein the semiconductor device has different threshold voltages according to a state of the ferroelectric or negative capacitance material layer.

25. A method of manufacturing a semiconductor device, comprising:
forming a dummy gate on a substrate;
forming a spacer on a sidewall of the dummy gate by using a ferroelectric or negative capacitance material; and
removing the dummy gate, and forming a gate electrode in a gate groove formed by a removal of the dummy gate on an inner side of the spacer.

26. The method according to claim 25, further comprising:
forming a ferroelectric or negative capacitance material layer in the gate groove.

27. A method for manufacturing a semiconductor device, comprising:
forming a dummy gate on a substrate;
forming a spacer on a sidewall of the dummy gate;
removing the dummy gate, and forming a ferroelectric or negative capacitance material layer in a gate groove formed by a removal of the dummy gate on an inner side of the spacer; and
forming a gate electrode in the gate groove on which the ferroelectric or negative capacitance material layer is formed.

28. The method according to claim 27, wherein the spacer is formed by using a ferroelectric or negative capacitance material.

29. The method according to claim 27, wherein
the ferroelectric or negative capacitance material layer is formed on a sidewall of the gate groove in form of spacer, or
the ferroelectric or negative capacitance material layer is continuously formed along a sidewall of the gate groove and a bottom surface of the gate groove.

30. The method according to claim 29, further comprising:
forming an interface layer on the sidewall of the gate groove and the bottom surface of the gate groove, wherein the ferroelectric or negative capacitance material layer is formed on the interface layer.

31. The method according to claim 29, further comprising:
forming a gate dielectric layer in the gate groove on which the ferroelectric or negative capacitance material layer in form of spacer is formed,
wherein the gate electrode is formed on the gate dielectric layer.

32. The method according to claim 31, further comprising:
forming a potential equalization layer in the gate groove on which the ferroelectric or negative capacitance material layer in form of spacer is formed,
wherein the gate dielectric layer is formed on the potential equalization layer.

33. The method according to claim 29, further comprising:
forming a gate dielectric layer on the ferroelectric or negative capacitance material layer continuously formed along the sidewall of the gate groove and the bottom surface of the gate groove,
wherein the gate electrode is formed on the gate dielectric layer.

34. The method according to claim 29, further comprising:
forming a gate dielectric layer on the sidewall of the gate groove and the bottom surface of the gate groove,
wherein the ferroelectric or negative capacitance material layer is continuously formed, on the gate dielectric layer, along the sidewall of the gate groove and the bottom surface of the gate groove, and the gate electrode is formed on the ferroelectric or negative capacitance material layer.

35. The method according to claim 29, further comprising:
forming a potential equalization layer on the gate dielectric layer,
wherein the ferroelectric or negative capacitance material layer is formed on the potential equalization layer.

36. An electronic apparatus, comprising the semiconductor device according to claim 1.

37. The electronic apparatus according to claim 36, wherein the electronic apparatus comprises a smart phone, a computer, a tablet computer, a wearable intelligent device, an artificial intelligence device, or a mobile power supply.
